(19) United States
(12) Patent Application Publication
(10) Pub. No.: US 2006/0203594 A1
(43) Pub. Date: Sep. 14, 2006

(54) Large voltage generation in semiconductor memory device

(76) Inventor: Tatsuya Matano, Tokyo (JP)

Correspondence Address: MCDERMOTT WILL & EMERY LLP, 600 13TH STREET, N.W., WASHINGTON, DC, 20005-3096, US

(21) Appl. No.: 11/371,934

(22) Filed: Mar. 10, 2006

(30) Foreign Application Priority Data
Mar. 11, 2005 (JP) 2005-069940

(51) Int. Cl. G11C 5/14

(52) U.S. Cl. 365/226

(57) ABSTRACT

A semiconductor memory device is disclosed. The device is provided with at least one purpose-specific voltage generator such as a VPP generator. The device is further provided with a circuit for generating a voltage for programming an anti-fuse element by the use of at least one of purpose-specific voltages such as a VPP. Preferably, the purpose-specific voltage is utilized for the programming voltage generation when being not used for its original purpose.

### BACKGROUND OF THE INVENTION

This invention relates to a semiconductor memory device and a method for generating a very large voltage therewithin.

In a semiconductor memory device such as a dynamic random access memory (DRAM) device, an anti-fuse technique is used for a post-package programming to replace a failure cell with a redundancy cell. An anti-fuse element is generally made of a very high resistive or electrically insulative component which is capable of being short-circuited by applying a programming voltage thereto in its programming operation. Normally, the programming voltage is very high, or the absolute value of the programming voltage is very large, and is also referred to as a super voltage (SVT). The SVT is generated by supplying a power supply voltage (VDD) to a single stage charge pump or multiple stages of charge pumps. For example, post-package failure repair techniques are disclosed in US 2004/213056 A1 and U.S. Pat. No. 6,240,033 B1, which are incorporated herein by reference in their entirety.

In order to avoid unintended short circuit of an anti-fuse element, it is necessary to provide the anti-fuse element with high voltage-resistance property, and accordingly, an SVT used for programming the high voltage-resistive anti-fuse must become very larger. To generate a very larger SVT from a VDD, many stages of charge pumps are needed so that its circuit size becomes large.

Therefore, there is a need for a novel voltage generation technique within a semiconductor memory, which can generate very larger SVT with its circuit size made as small as possible.

### SUMMARY OF THE INVENTION

Normally, in a semiconductor memory device such as a DRAM device, there have been already included purpose-specific voltage generators, for example, a VBB generator and a VPP generator; the VBB generator is adapted to generate a negative voltage applied as a reverse bias voltage to the substrate of the device, and the VPP generator is adapted to generate a high voltage used for driving word lines. In addition, at least one of the purpose-specific voltage generators, for example the VPP generator, can generate a voltage whose absolute value is larger than that of a VDD but is smaller than that of a required SVT.

According to an aspect of the present invention, an SVT is generated by the use of the at least one purpose-specific voltage generator which has been already included in a semiconductor memory device. In other words, according to an aspect of the present invention, at least one purpose-specific voltage generator is used not for generating its original-purpose voltage but for generating an SVT during a post-package repair process.

An appreciation of the objectives of the present invention and a more complete understanding of its structure may be had by studying the following description of the preferred embodiment and by referring to the accompanying drawings.

### BRIEF DESCRIPTION OF THE DRAWINGS

FIG. 1 is a block diagram schematically showing a partial structure of a semiconductor memory device according to a first embodiment of the present invention;

FIG. 2 is a block diagram schematically showing the voltage generation controller of FIG. 1;

FIG. 3 is a circuit diagram schematically showing the oscillator of FIG. 2;

FIG. 4 is a circuit diagram schematically showing the pulse controller of FIG. 2, wherein the pulse controller includes two types of level shifters;

FIG. 5 is a circuit diagram schematically showing one type of the level shifters of FIG. 4;

FIG. 6 is a circuit diagram schematically showing the other type of the level shifters of FIG. 4;

FIG. 7 is a circuit diagram schematically showing the charge pump circuit of FIG. 1;

FIG. 8 is a timing chart for use in describing the operation of the charge pump circuit of FIG. 7;

FIG. 9 is a block diagram schematically showing a partial structure of a semiconductor memory device according to a second embodiment of the present invention;

FIG. 10 is a block diagram schematically showing the voltage generation controller of FIG. 9;

FIG. 11 is a circuit diagram schematically showing the pulse controller of FIG. 10, wherein the pulse controller includes three types of level shifters;

FIG. 12 is a circuit diagram schematically showing one type of the level shifters of FIG. 11;

FIG. 13 is a circuit diagram schematically showing the charge pump circuit of FIG. 9; and

FIG. 14 is a timing chart for use in describing the operation of the charge pump circuit of FIG. 13;

### DESCRIPTION OF PREFERRED EMBODIMENTS

A semiconductor memory device according to a first embodiment of the present invention is a DRAM device, which comprises a memory cell array, word lines, bit lines, a redundancy cell block and anti-fuse elements.

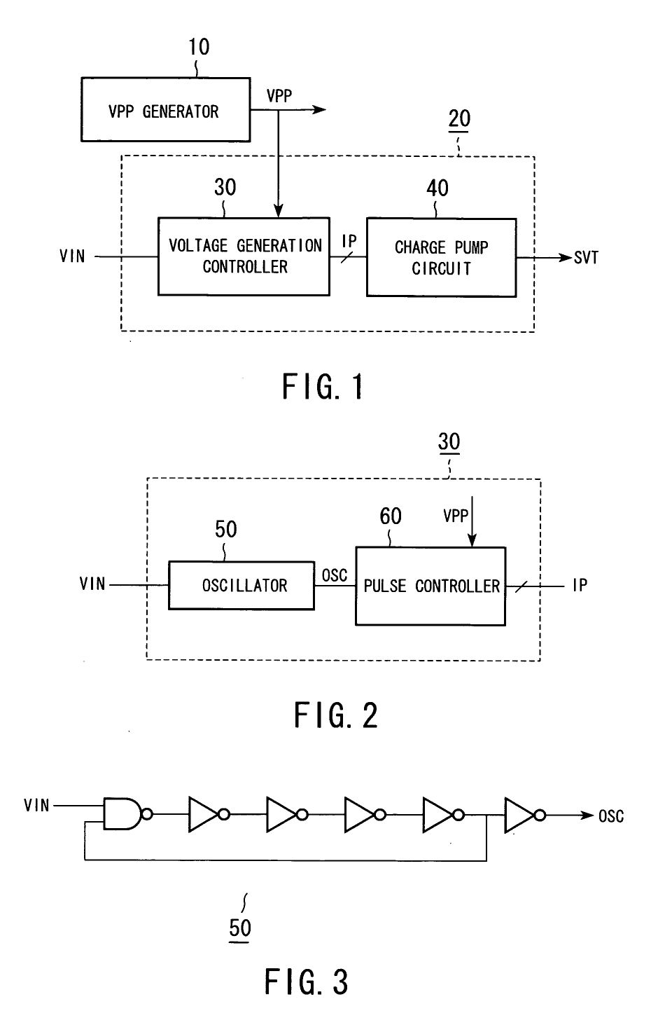

As shown in FIG. 1, the semiconductor memory device of the first embodiment comprises a VPP generator 10 adapted to generate from a VDD signal a VPP signal which is used for driving the word lines included in the DRAM device. The semiconductor memory device of the first embodiment further comprises an SVT generator 20 coupled to the VPP generator 10 and adapted to generate from the VPP signal an SVT signal which is used for programming the anti-fuse elements included in the DRAM device. In this embodiment, the programming voltage is lower than zero voltage but its absolute value is larger than the VPP. However, the programming voltage may be a positive one and be higher than the VPP. In addition, the SVT generator may be adapted to at first produce a negative SVT and then to produce a positive SVT by using the negative SVT.

The illustrated SVT generator 20 comprises a voltage generation controller 30 and a charge pump circuit 40 coupled to the voltage generation controller 30.

The voltage generation controller 30 is further coupled to the VPP generator 10 and is adapted to receive a voltage generation signal and to produce a set of control signals and a set of base voltage signals when the voltage generation signal is asserted, wherein the control signals and the base voltage signals are collectively depicted with “IP” in FIGS. 1 and 2, and the voltage generation signal is depicted with “VIN” in the same drawings. Each of the base voltage signals is used for generating the SVT signal at the charge pump circuit 40, and its voltage absolute value is equal to that of the VPP signal.

The charge pump circuit 40 is adapted to produce the SVT signal from the base voltage signal in accordance with the set of control signals. In detail, the charge pump circuit 40 produces the SVT signal by boosting or stepping up the voltage absolute value of the base voltage signal under the control according to the set of control signals.

As shown in FIG. 2, the voltage generation controller 30 comprises an oscillator 50 and a pulse controller 60 coupled to the oscillator 50 and the VPP generator 10. The oscillator 50 is adapted to produce an oscillation signal in response to the asserted voltage generation signal; the oscillation signal is depicted with “OSC” in FIG. 2. The pulse controller 60 is adapted to produce the control signals and the base voltage signal from the oscillation signal and the VPP signal.

As shown in FIG. 3, the oscillator 50 of the present embodiment is a ring oscillator which comprises a first stage NAND gate, subsequent even-numbered stages of inverters and a final stage inverter. The NAND gate has two inputs. One of the inputs is supplied with the voltage generation signal “VIN”. To the other input, the output of the last stage inverter among the even-numbered stages of the inverters, i.e. the input for the final stage inverter, is fed back.

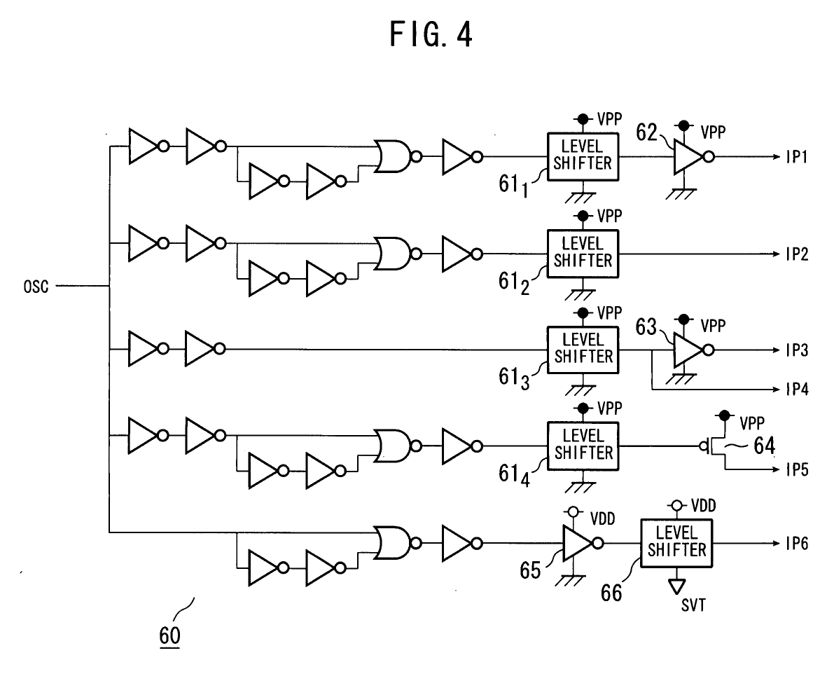

As shown in FIG. 4, the pulse controller 60 of the present embodiment receives the oscillation signal from the oscillator 50 and produces first to fourth control signals IP1, IP2, IP4 and IP6 as well as first and second base voltage signals IP3 and IP5. In order to produce the signals IP1 to IP6, the illustrated pulse controller 60 comprises five parallel process lines in each of which a timing adjustment/waveform regulation processing for the received oscillation signal is carried out. Each of the parallel process lines of the timing adjustment/waveform regulation processing is designed in consideration of timing margins which are required for desirable boosting or stepping up operation in the subsequent charge pump circuit 40.

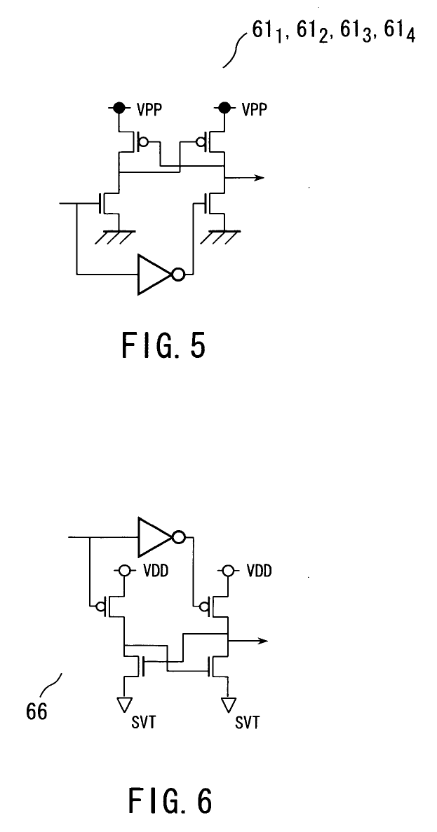

In detail, in each of the top four process lines shown in FIG. 4, the regulated oscillation signal is supplied to a level shifter 61₁, 61₂, 61₃, or 61₄. The level shifter 61₁, 61₂, 61₃, or 61₄ has a circuit structure shown in FIG. 5 and produces an output signal which is in phase with an input signal for the level shifter 61₁, 61₂, 61₃, or 61₄, i.e. each regulated oscillation signal, and whose amplitude is determined by the difference between the GND and the VPP.

The output signal of the level shifter 61₁ is delivered, as the first control signal IP 1, through an inverter 62 to the charge pump circuit 40. The output signal of the level shifter 61₂ is delivered as the second control signal IP2 to the charge pump circuit 40. The output signal of the level shifter 61₃ is branched off in two signals; one of which is delivered, as the j first base voltage signal IP3, through an inverter 63 to the charge pump circuit 40, while the other is delivered as the third control signal IP4 to the charge pump circuit 40 directly. Apparently from this explanation, the first base voltage signal IP3 and the third control signal IP4 constitute a complementary signal pair. In this embodiment, the inverter 63 is provided with the VPP but may be provided with the VDD. In case of the VDD provided for the inverter 63, the voltage absolute value of the SVT is lowered in comparison with the illustrated structure. The output signal of the level shifter 61₄ is delivered to a PMOS transistor 64, which is in ON state when “L” level signal is provided for its gate, while being in OFF state when “H” level signal is provided for its gate. The state of the transistor 64 determines the content of the second base voltage signal IP5. Namely, the second base voltage signal IP5 is fixed to the VPP when the “L” level signal is provided for the gate of the transistor 64, while the second base voltage signal IP5 has a high impedance (HiZ) when the “H” level signal is provided for the gate of the transistor 64.

In the lowermost process lines shown in FIG. 4, the regulated oscillation signal is supplied through an inverter 65 to another level shifter 66. The level shifter 66 has a circuit structure shown in FIG. 6 and produces an output signal which is in phase with an input signal for the level shifter 66, i.e. the regulated oscillation signal at the lowermost process line, and whose amplitude is determined by the difference between the VDD and the SVT, i.e. VDD-SVT. The output signal of the level shifter 66 is delivered as the fourth control signal IP6 to the charge pump circuit 40.

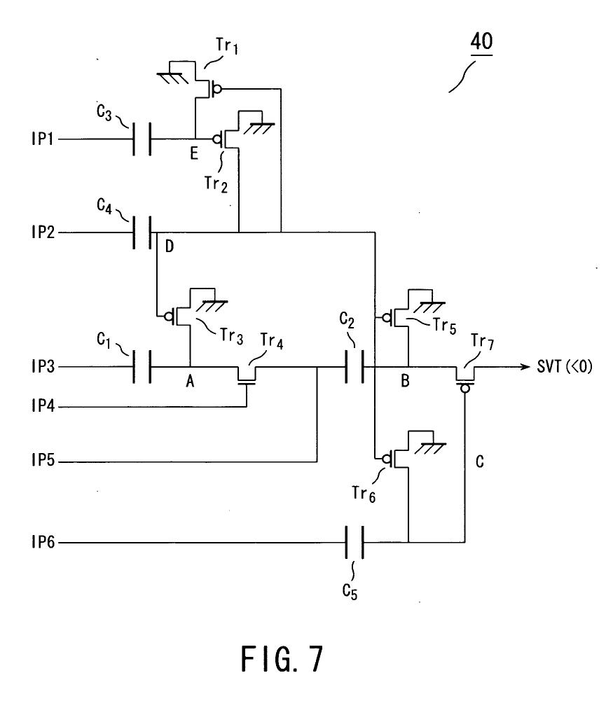

As shown in FIG. 7, the charge pump circuit 40 comprises capacitors C₁, C₂, transistor switches Tr₁˜Tr₇, and coupling capacitors C₃˜C₅. The capacitors C₁, C₂ are for storing electrical charges by the first and the second base voltage signals IP3 and IP5, respectively. The transistors Tr₁˜Tr₃ and Tr₅˜Tr₆ are PMOS transistors whose states are changed by the first and the second control signals IP1, IP2; each of the transistors Tr₁˜Tr₃ and Tr₅˜Tr₆ is in ON state when a predetermined negative level is provided for its gate, while being in OFF state when the GND level is provided for its gate. The transistor Tr₄ is an NMOS transistor whose state is changed by the third control signal IP4; the transistor Tr₄ is in ON state when a predetermined positive level is provided for its gate, while being in OFF state when the GND level is provided for its gate. The transistor Tr₇ is a PMOS transistor whose state are changed by the fourth control signal IP6; the transistor Tr₇ is in ON state when a predetermined negative level is provided for its gate, while being in OFF state when the GND level is provided for its gate. Each of the coupling capacitors C₃˜C₅ is for passing a A.C. component of a signal input into the capacitor while blocking a D.C. component of the input signal.

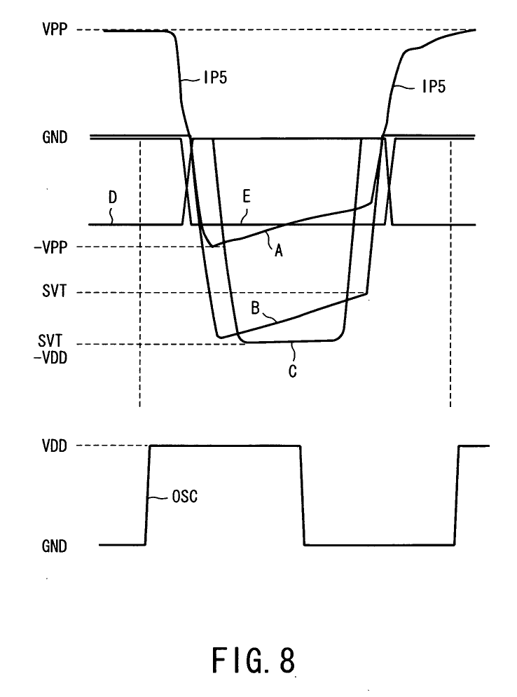

With the above structure, charges by the first base voltage signal IP3 are held in the capacitor C₁, while charges by the second base voltage signal IP5 is held in the capacitor C₂. By switching the transistors Tr₁˜Tr₇, the charges stored in the capacitor C₁ are transferred to the capacitor C₂ so that the large voltage are generated between the opposite plates of the capacitor C₂, as shown in FIG. 8.

Now detail explanation will be made about the charge pump operation shown in FIG. 8 with reference also to FIG. 7.

First, assuming that the first control signal IP1 has “H” level and that the second control signal IP2 has “L” level. At that time, the transistors Tr₁, Tr₃, Tr₅, Tr₆ are in ON states, while transistor Tr₂ is in OFF state. At the result, electrical potentials on points A, B, C and E depicted in FIG. 7 become GND while another potential on point D becomes a negative voltage level. Because of the potential on the point C, the transistor Tr₇ is in OFF state. At that time, the first base voltage signal has the VPP level (higher level) and, on the other hand, the third control signal IP4 has the GND level so that the transistor Tr₄ is in OFF state.

Next, assuming that the first control signal IP1 has “L” level and that the second control signal IP2 has “H” level. At that time, the transistors Tr₁, Tr₃, Tr₅, Tr₆ become in OFF states, while transistor Tr₂ becomes in ON state; an electrical potential on point E becomes a negative voltage level so that the another electrical potential on the point D becomes GND. As the result, voltage changes occur on the points A˜C.

In addition, assuming that the transistor Tr₂ is in ON state, that the first base voltage signal IP3 has the GND level, that the second base voltage signal IP5 is in the HiZ state, and that the third control signal IP4 is in the “H” level. At that time, the transistor Tr₄ becomes in ON state so that the charges stored in the capacitor C₁ and the charges stored in the capacitor C₂ are added to each other. Therefore, the voltage level on the point B becomes lowered drastically.

Assuming that the fourth control signal IP6 has the VDD level when the transistor Tr₆ is in ON state. Further assuming that the state changes therefrom so that the transistor Tr₆ is in OFF state and the fourth control signal IP6 has the SVT level. At that time, the voltage level on the point C becomes “−VDD+SVT.” Therefore, the transistor Tr₇ is in ON state and outputs, as the SVT, the potential on the point B. In this embodiment, the fourth control signal IP6 is regulated so as to cause the transistor Tr₇ to be in ON state after the electrical potential on the point B is lowered sufficiently.

As described in detail, the semiconductor memory device of the present invention produces the SVT in response to the asserted voltage generation signal (VIN). The voltage generation signal is asserted only when the VPP signal generated by the VPP generator is not used for driving the word lines of the memory device. That is to say, in this embodiment, the VPP generator is utilized to generate the SVT only when the VPP generator does not operate for its own specific purpose, i.e. the driving the word lines.

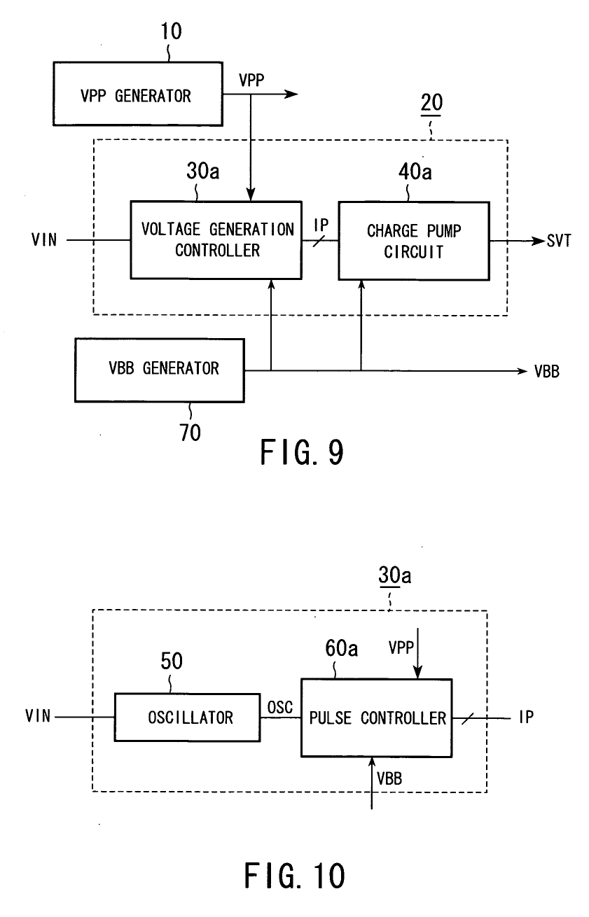

With reference to FIGS. 9 to 14, a semiconductor memory device according to a second embodiment of the present invention is the modification of the above-described first embodiment. The semiconductor memory device of the present embodiment further comprises a VBB generator 70 and uses, for an SVT generation, a VBB signal generated by the VBB generator 70. Between the associated figures of the first and the second embodiments, note that the same reference numerals are used to designate like elements.

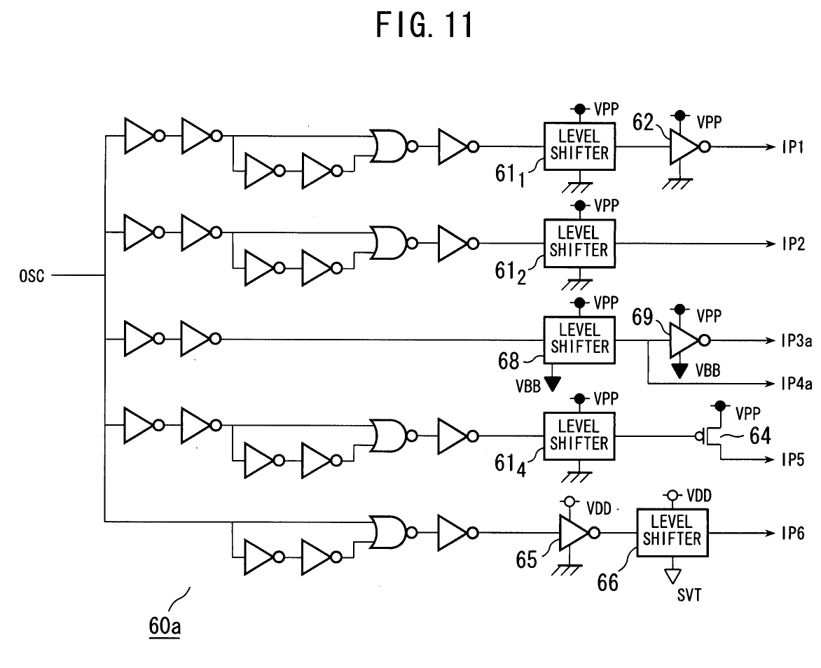

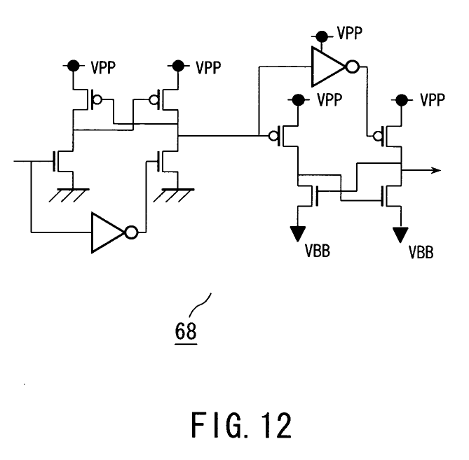

As shown in FIGS. 9 and 10, the VBB signal generated by the VBB generator 70 is provided for a voltage generation controller 30a, especially, a pulse controller 60a. The pulse controller 60a comprises a circuit structure illustrated in FIG. 11. As apparent from the comparison between FIGS. 4 and 11, the pulse controller 60a of the present embodiment has the same structure of the pulse controller 60 of the first embodiment except that the pulse controller 60a comprises a level shifter 68 and an inverter 69 instead of the level shifter 61₃ and the inverter 63, respectively. The level shifter 68 has a circuit structure shown in FIG. 12 and produces an output signal which is in phase with an input signal for the level shifter 68 and whose amplitude is determined by the difference between the VBB and the VPP. The output signal of the level shifter 68 is branched off in a first base voltage signal IP3a and a third control signal IP4a. Because the third control signal IP4 is delivered from the level shifter 68 to the charge pump circuit 40 directly, the maximum amplitude of the third control signal IP4 is determined by the difference between the VBB and the VPP. On the other hand, because the inverter 69 is provided with the VBB level instead of the GND level, the maximum amplitude of the first base voltage signal IP3a is determined by the difference between the VBB and the VPP. Apparently from this explanation, the first base voltage signal IP3a and the third control signal IP4a constitute a complementary signal pair, similar to the first embodiment.

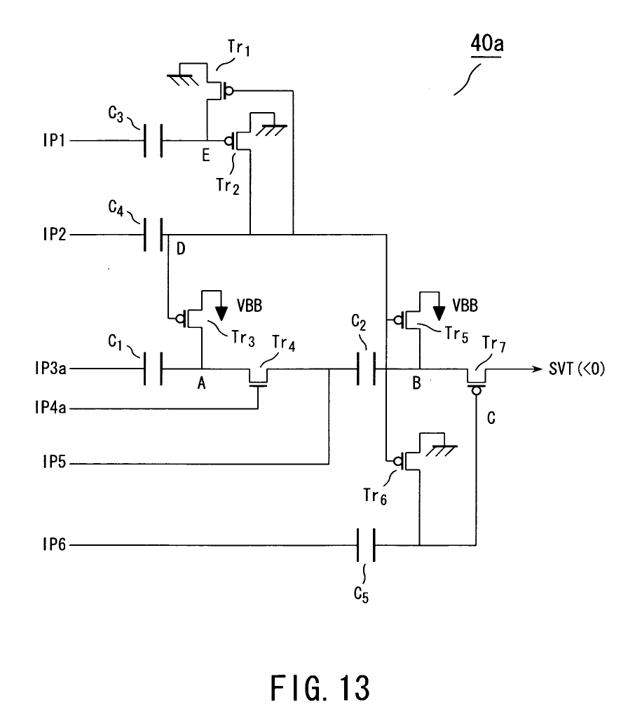

As shown in FIGS. 9 and 13, the VBB signal generated by the VBB generator 70 is also provided for a charge pump circuit 40a. The charge pump circuit 40a comprises a circuit structure illustrated in FIG. 13. As apparent from the comparison between FIGS. 7 and 13, the charge pump circuit 40a of the present embodiment has the same structure of the charge pump circuit 40 of the first embodiment except for the use thereof. In this embodiment, the transistors Tr₃ and Tr₅ are provided with the VBB instead of the GND.

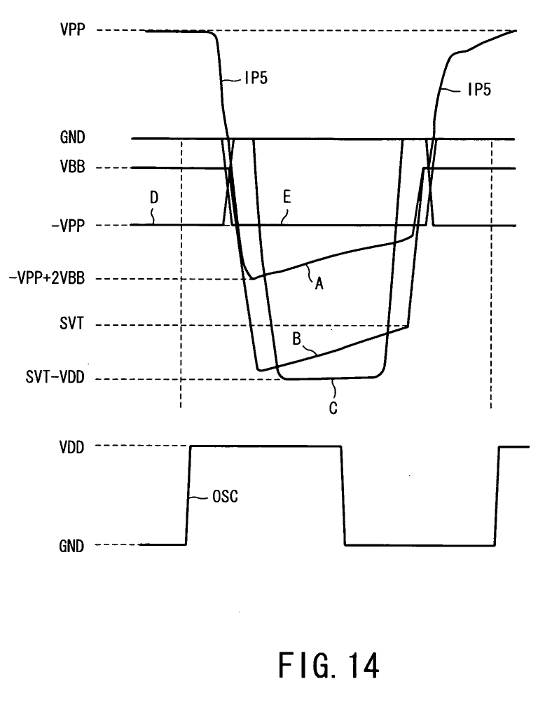

With the above structure, electrical charges storable in the capacitor C₁ increases by double the VBB (2VBB). Electrical charges storable in the capacitor C₂ increases by 2VBB, too. Therefore, the SVT produced by the present embodiment is larger than that of the first embodiment, as shown in FIG. 14.

The preferred embodiments of the present invention will be better understood by those skilled in the art by reference to the above description and figures. The description and preferred embodiments of this invention illustrated in the figures are not to intend to be exhaustive or to limit the invention to the precise form disclosed. They are chosen to describe or to best explain the principles of the invention and its applicable and practical use to thereby enable others skilled in the art to best utilize the invention.

While there has been described what is believed to be the preferred embodiment of the invention, those skilled in the art will recognize that other and further modifications may be made thereto without departing from the sprit of the invention, and it is intended to claim all such embodiments that fall within the true scope of the invention.

What is claimed is:

1. A semiconductor memory device comprising:
a first voltage generator adapted to generate a first voltage signal for a first specific purpose, the first voltage signal having a first voltage absolute value larger than an absolute value of a power supply voltage;
a terminal adapted to receive a voltage generation signal; and
a second voltage generator coupled to the terminal and the first voltage generator and adapted to generate a second voltage signal by the use of the first voltage signal when the voltage generation signal is asserted, the second voltage signal being for a second specific purpose different from the first specific purpose, the second voltage signal having a second voltage absolute value larger than the first voltage absolute value.

2. The semiconductor memory device according to claim 1, wherein the second voltage generator comprises:
a voltage generation controller coupled to the terminal and the first voltage generator and adapted to produce a control signal and a base voltage signal from the voltage generation signal and the first voltage signal, the base voltage signal having a voltage absolute value equal to the first voltage absolute value; and
a charge pump circuit coupled to the voltage generation controller and adapted to receive the control signal and the base voltage signal to produce the second voltage signal.

3. The semiconductor memory device according to claim 2, wherein the charge pump circuit produces the second voltage signal by boosting up the voltage absolute value of the base voltage signal in response to the control signal.

4. The semiconductor memory device according to claim 2, wherein the voltage generation controller comprises:
an oscillator coupled to the terminal and adapted to produce an oscillation signal in response to the asserted voltage generation signal; and
a pulse controller coupled to the oscillator and the first voltage generator and adapted to produce the control signal and the base voltage signal from the oscillation signal and the first voltage signal.

5. The semiconductor memory device according to claim 1, wherein the first voltage signal is a VPP signal, while the second voltage signal is a programming voltage signal for anti-fuse element.

6. The semiconductor memory device according to claim 5, further comprising a VBB generator coupled to the second voltage generator and adapted to generate a reverse bias voltage signal to deliver the reverse bias voltage signal to the second voltage generator, the reverse bias voltage signal having a negative voltage level, wherein the second voltage generator generates the second voltage signal by the use of a voltage level-difference between the first voltage signal and the reverse bias voltage signal.

7. The semiconductor memory device according to claim 1, comprising a DRAM device including the first voltage generator, the terminal, and the second voltage generator.

8. The semiconductor memory device according to claim 1, wherein the voltage generation signal is asserted only when the first voltage signal is not used for the first specific purpose.

9. A use of the semiconductor memory device according to claim 1, wherein the voltage generation signal supplied to the terminal is negated when the first voltage signal is used for the first specific purpose, and the voltage generation signal is asserted only when the first voltage signal is not used for the first specific purpose.

10. A semiconductor memory device including:
a VPP generator adapted to generate a VPP signal; and
an SVT generator coupled to the VPP generator and adapted to generate an SVT signal from the VPP signal.

11. The semiconductor memory device according to claim 10, wherein the SVT generator comprises a charge pump circuit and a voltage generation controller coupled to the charge pump circuit and the VPP generator, the voltage generation controller being adapted to control the charge pump circuit so that the charge pump circuit generates the SVT signal.

12. The semiconductor memory device according to claim 11, wherein the voltage generation controller is further adapted to supply the charge pump circuit with the VPP signal or a signal having an absolute value equal to that of the VPP signal.
